(19) United States
(12) Patent Application Publication
(10) Pub. No.: US 2010/0253629 A1
(43) Pub. Date: Oct. 7, 2010

(54) Combined Mutual Capacitance and Switch-Actuated Keyboard for Enhanced Texting in an Electronic Device

(75) Inventor: Timothy James Orsley, San Jose, CA (US)

Correspondence Address: Kathy Manke;Avago Technologies Limited, 4380 Ziegler Road, Fort Collins, CO, 80525, US

(73) Assignee: Avago Technologies ECBU IP (Singapore) Pte. Ltd., Singapore (SG)

(21) Appl. No.: 12/418,232

(22) Filed: Apr. 3, 2009

(51) Int. Cl. G09G 5/00; H03K 17/94

(52) U.S. Cl. 345/168; 341/22

(57) ABSTRACT

In one embodiment, a mutual-capacitance sensing electrode array is disposed beneath a keyboard, and operates in conjunction with a series of single switches disposed beneath each of the keys in a keyboard. The electrode array and switches are employed in conjunction with one another to indicate that a letter, number or other symbol displayed on a particular key has been selected by a user. Although some embodiments find especially efficacious application in hand-held portable electronic devices such as mobile telephones, other embodiments are well suited for use in stationary equipment or other devices containing keyboards or control panels.

### FIELD OF THE INVENTION

Various embodiments of the invention described herein relate to the field of electronic devices having capacitive sensing keyboards, and more specifically to mutual capacitance measurement or sensing keyboards for such devices that are configured to operate in conjunction with switch-actuated devices to provide improved texting ability. Such keyboards find particularly efficacious applications in hand-held portable electronic devices such as telephones, PDAs, MP3 players, personal computers, game controllers, laptop computers, and the like. Also described are embodiments adapted for use in stationary applications such as in industrial controls, washing machines, exercise equipment, and the like.

### BACKGROUND

Text messages are often generated on portable electronic devices such as mobile phones by using multiple keystrokes to select from among a plurality of letters associated with a given key. For example, the letters “A”, “B” and “C” are typically associated with the number “2” key on a conventional mobile phone keyboard. In text mode, to select the latter “A” the “2” key is pressed once. To select the letter “B,” the “2” key is pressed twice, and to select the letter “C” the “2” key is pressed three times. What is needed are means and methods for selecting such letters on a keypad for a portable or stationary electronic device more quickly and easily.

### SUMMARY

In one embodiment, there is provided a combined mutual capacitance and switch-actuated keyboard for an electronic device comprising a keyboard comprising a plurality of keys arranged in rows and columns, at least some of the keys in the keyboard each having a single switch disposed therebeneath, each key and switch being configurable to present, assume or sense at least left and right positions according to how each such key is engaged, depressed, tilted or touched by a user's finger, namely a left position and a right position, each of the at least some keys having first and second symbols displayed thereon, the first and second symbols corresponding to the left and right positions of each of switches, a first plurality of drive electrodes disposed beneath the rows or columns of the keyboard, the drive electrodes in each row or column being electrically independent of one another, a second plurality of sense electrodes disposed beneath the rows or columns of the keyboard, the sense electrodes in each row or column being electrically independent of one another, wherein the first plurality of drive electrodes is arranged at an angle with respect to the second plurality of sense electrodes, the rows and columns of drive and sense electrodes cross over but are electrically isolated from one another at locations beneath the at least some keys, at least two sense electrodes corresponding to the left and right positions are disposed beneath each of the at least some keys, the drive and sense electrodes form an array configured in respect of the keyboard to permit the first and second positions selected by the user's finger and corresponding to each of the at least some keys to be detected by the array, and each switch is configured to indicate the user's finger's selection of the first or second symbol.

In a further embodiment, such switch and key is further configurable to assume a central position, and each of the at least some keys has a third symbol displayed thereon, the third symbol corresponding to the central position of each of the at least some keys, each such switch and key further being configured to indicate selection of the first, second or third symbol.

In another embodiment, there is provided a method of generating text messages with an electronic device comprising a user's finger engaging, touching, depressing or tilting a key on a keypad to or in a left position or a right position to select one of at least two letters, numbers or symbols displayed on the key at the left and right positions, respectively, capacitively sensing, using at least first and second sense electrodes disposed beneath the left and right positions of the key, and at least one drive electrode disposed beneath the key, the letter, number or symbol that has been selected by the user's finger, and causing a single switch disposed beneath each such key to indicate which of the left and right positions has been selected by the user's finger, wherein the switch is mechanically, capacitively or resistively configurable to indicate the left and right positions according to whether the user's finger selects the left position or the right position.

In a further embodiment, the method comprises the user's finger selecting the key on the keypad in a central position to select one of at least three letters, numbers or symbols displayed on the key at the central position and capacitively sensing, using at least a third sense electrode disposed beneath the central position of the key, and at least one drive electrode disposed beneath the key, the letter, number or symbol that has been selected by the user, wherein the switch is further mechanically, capacitively or resistively configurable to indicate the central position according to whether the user's finger selects the central position.

Further embodiments are disclosed herein or will become apparent to those skilled in the art after having read and understood the specification and drawings hereof.

### BRIEF DESCRIPTION OF THE DRAWINGS

Different aspects of the various embodiments of the invention will become apparent from the following specification, drawings and claims in which:

FIG. 1 shows a top plan view of one embodiment of a keyboard forming a portion of a mobile hand-held electronic device, with accompanying close-up views of a portion of the keyboard;

FIG. 2 shows a top plan view of the mobile hand-held electronic device of FIG. 1 with a location of a mutual capacitance sense and drive electrode array superimposed on the keyboard thereof;

FIG. 3 shows a cross-sectional view of one embodiment of a single key and corresponding switch and sense and drive electrodes;

FIG. 4 shows a top plan view of another embodiment of a mobile hand-held electronic device with a location of a mutual capacitance sense and drive electrode array superimposed on a keyboard thereof, and

FIG. 5 shows a capacitance measurement or sensing circuit 72 according to one embodiment.

The drawings are not necessarily to scale. Like numbers refer to like parts or steps throughout the drawings.

### DETAILED DESCRIPTION OF SOME PREFERRED EMBODIMENTS

Incorporated by reference herein, each in its respective entirety, are: (1) U.S. patent application Ser. No. 12/024,057 to Harley et al. entitled “Single Layer Mutual Capacitance Sensing Systems, Devices, Components and Methods” filed Jan. 31, 2008; and (2) U.S. patent application Ser. No. 12/183,456 to Harley entitled “Capacitive Touchscreen or Touchpad for Finger or Stylus” filed Jul. 31, 2008.

In some of the various embodiments of the invention described herein, a mutual-capacitance sensing electrode array is disposed beneath a keyboard in an electronic device, and operates in conjunction with single switches disposed beneath corresponding keys in the keyboard, thereby to indicate a letter, number or other symbol displayed on a particular key that has been selected by a user when the device is operating in texting mode.

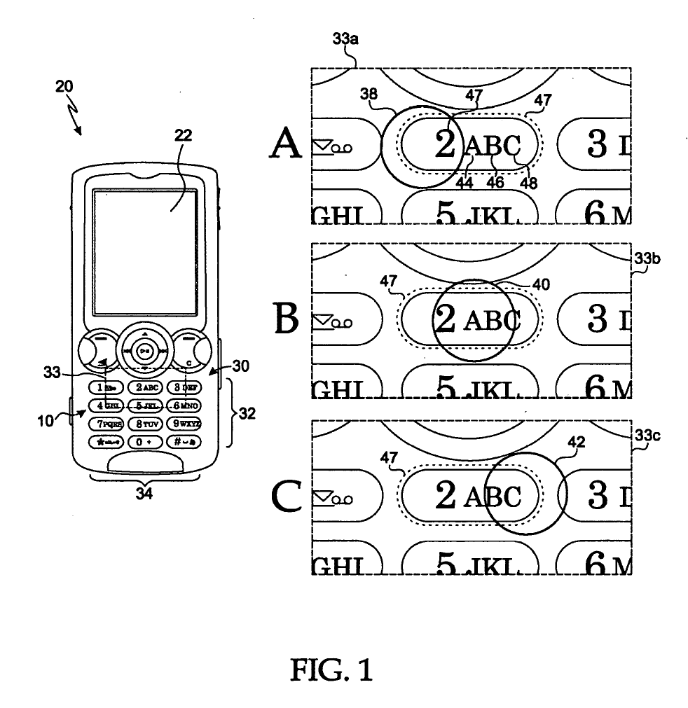

FIG. 1 shows a top plan view of one embodiment of keyboard 30 forming a portion of mobile or hand-held electronic device 20 with screen 22, with accompanying top-to-bottom close-up views 33a-33c of a portion of keyboard 30. Keyboard 10 comprises a plurality of keys 30 arranged in rows 32 and columns 34, at least some of keys 30 in keyboard 10 each having a single switch 36 disposed therebeneath (not shown in FIG. 1, and more about which is said below), where each such switch is configurable to assume or indicate left, center and right positions 38, 40 and 42 according to the particular manner in which such keys 30 are depressed by a user's finger. In one embodiment, and as further described in detail below, switch 36 is a finger-tiltable and/or finger-depressible mechanical switch. Note, however, the switch 36 may assume any of myriad different forms and configurations, such as a switch that is depressible but not tiltable, a membrane switch, a capacitively- or resistively-operated switch, or any other suitable switch type, as those skilled in the art will now understand.

A left-tilted and finger-depressed left position 38 is shown in top close-up view 33a of FIG. 1. A right-tilted and finger-depressed right position 42 is shown in bottom close-up view 33c, while a substantially untilted and finger-depressed central position 40 is shown in the central close-up view 33b of FIG. 1. As further shown in the embodiment of FIG. 1, most or all of keys 30 may have first, second and third symbols displayed thereon, where the first, second and third symbols correspond to the left, center and right positions 38, 40 and 42 of each of the switches 36 disposed beneath each of the keys (not shown in FIG. 1). Note that it is not required that all keys have three symbols on each key from among which a user may choose. Some keys may have only one symbol, two symbols or even four symbols, depending on the particular keyboard design and the desired functionality.

Referring still to FIG. 1, and as further shown in close-up views 33a-33c, the “2” key (47) has displayed or embossed thereon three letters “A” (44), “B” (46) and “C” (48). When device 20 is in texting mode, and by way of example, a user can press key 47 to select the letters “A”,” “B” or “C,” respectively, by pressing or toggling key 47 into the left position (38), the center position (40) or the right position (42), thereby eliminating the need to employ multiple key strokes to select a given desired symbol.

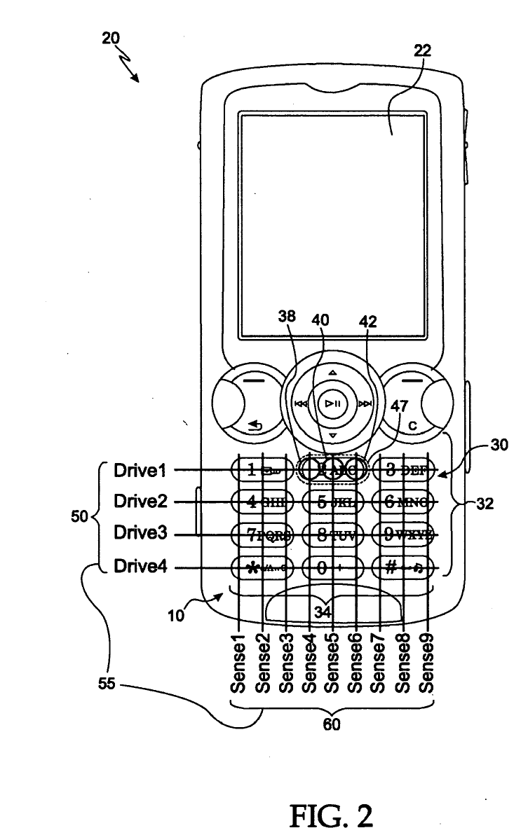

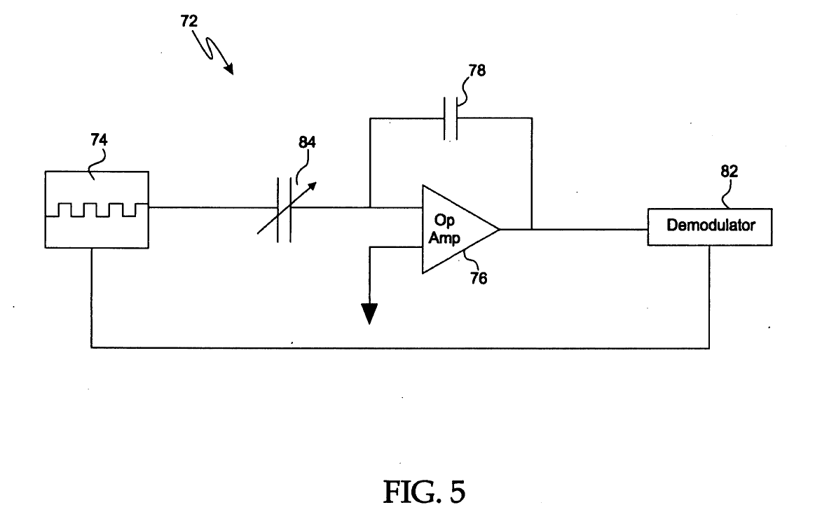

FIG. 2 shows a top plan view of mobile hand-held electronic device 20 of FIG. 1 with the location of mutual capacitance sense and drive electrode array 55 superimposed on keyboard 10 thereof. As shown, a first plurality of drive electrodes 50 is disposed beneath rows 32 of keys 30 of keyboard 10, where the individual drive electrodes in each row are electrically independent of one another. A second plurality of sense electrodes 60 is disposed beneath the columns of keys 30 of keyboard 10, where the individual sense electrodes in each column are electrically independent of one another. In a preferred embodiment, each electrode in each of the first plurality of drive electrodes and second plurality of sense electrodes is connected to its own pin of an integrated circuit which forms capacitance sensing circuit 72 (see, e.g., FIG. 5). That is, there is no ohmic contact between, and there is electrical isolation between, the various individual electrodes of mutual capacitance sense and drive electrode array 55.

In the embodiment illustrated in FIG. 2, rows 32 of the first plurality of drive electrodes 50 are substantially perpendicular to columns 34 of the second plurality of sense electrodes 60, and rows 32 and columns 34 of drive and sense electrodes 50 and 60 cross over, but are electrically isolated from one another, at predetermined specific locations beneath keys 30, where three sense electrodes correspond to the left, center and right positions 38, 40 and 42 of each key and are disposed beneath such keys. As further illustrated in FIG. 2, drive and sense electrodes 50 and 60 form an array 55 configured in respect of keyboard 10 to permit the first, second and third positions 38, 40 and 42 corresponding to each of the keys 30, as the selected key portion is depressed by a user, to be detected by array 55. Switch 36 (not shown in FIG. 2) disposed beneath each key is configured to be closed when depressed downwardly sufficiently far thereby to indicate selection of a symbol on the key, and optionally also to permit a user's finger to be brought into close enough proximity to the electrode array such that the particular portion or position 38, 40 or 42 of the key which the user is selecting and depressing may be sensed by the array. Alternatively, array 55 may be configured to detect the position of a user's finger on keyboard 10 even though no key 30 has been depressed.

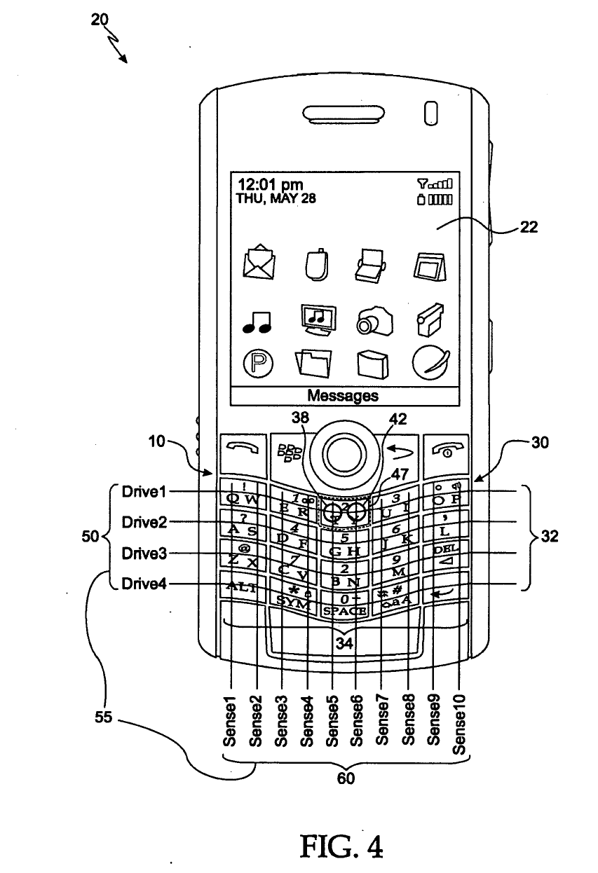

Note that according to the particular application or keyboard at hand, drive electrodes 50 may alternatively be arranged in columns, while sense electrodes 60 s may be arranged in rows. Note further that the rows or columns of sense and drive electrodes need not be arranged perpendicular in respect one another, but instead may be arranged at any suitable angle. In addition, drive and sense electrodes 50 and 60 of FIG. 4 may be arranged substantially in a single plane, may be disposed on opposing surfaces of a suitable substrate 52 (not shown in FIG. 2), or may be otherwise suitably configured in respect of one another such as in multiple different planes. A substrate 52 (not shown in FIG. 2) upon which array 55 may be formed or disposed can be formed a bendable or flexible material such as a flex circuit material. In addition, the electrically conductive traces employed to form drive and sense electrodes of electrode array 55 may comprise, for example, indium tin oxide (“ITO”), copper, tin, or any other suitable electrically conductive material, metal, metal combination or metal alloy. Note that a ground plane may also be provided beneath electrode array 55, and to which portions of electrode array 55 may be connected electrically.

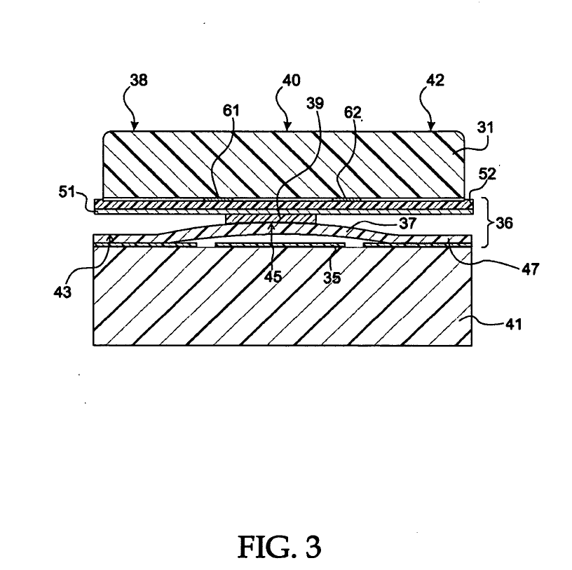

Referring now to FIG. 3, there is shown a cross-sectional view of one embodiment of a single key 31 and corresponding switch 36, substrate 52, sense electrodes 61 and 62, and drive electrode 51. In the embodiment shown in FIG. 3, key 31 is located above depressible dome 37 having a top-most portion 45 thereof which engages plunger 39. When key 31 is pressed downwardly by a user, plunger 39 pushes top-most portion 45 downwardly until it engages contact 35 disposed therebelow, thereby completing a circuit and providing a signal indicating that key 31 has been actuated by a user. Contact 35 is preferably disposed above an underlying base layer or substrate 41. Substantially simultaneously, sense and drive electrodes 61, 62 and 51 sense and detect where the user has pressed key 31, namely at one of positions 38, 40 or 42, respectively. Thus, hand-held device 20 receives first information or a first signal indicating switch 31 has been actuated or closed by a user at or about the same time that second information or a second signal is provided indicating into which particular position 38, 40 or 42 key 31 has been pressed by the user. The first information and second signals are preferably combined to yield third information or a third signal indicating which from among three symbols the user has selected when device 20 is in texting mode.

As mentioned above, not all keys need be provided with switch 36 and/or electrodes 61, 62 and 51, and thus some keys may feature reduced functionality respecting those keys which do include switch 36 and/or electrodes 61, 62 and 51. Moreover, keys 30, switches 36, and electrodes 50 and 60 are not limited to being configured to detect three different symbols and corresponding positions per key, but may also be configured to detect only two positions for each key (more about which is said below), or more than three positions for each key. Indeed, by using interpolation techniques more key positions for a given key may be sensed than the number of sense electrodes provided beneath such given key. In addition, and depending on the particular application and keyboard at hand, an appropriate number of sense and drive electrodes may be selected for positioning beneath the keys such that two, three, or four positions, by way of example, may be detected for some keys, all keys or only one key.

Referring now to FIG. 4, there is shown a top plan view of another embodiment of mobile hand-held electronic device 20 with a location of mutual capacitance sense and drive electrode array 55 superimposed on keyboard 10 thereof. Note that in the embodiment illustrated in FIG. 4, keyboard 10 comprises more keys 30 than that of keyboard 10 illustrated in FIGS. 1 and 2, and also features an additional column of sense electrodes. Instead of a twelve keys, keyboard 10 of FIG. 4 has twenty keys, and instead of nine columns of sense electrodes, keyboard 10 of FIG. 4 has ten columns of sense electrodes. In addition, most of keys 30 in FIG. 4 have two letters displayed thereon such that when device 20 is operating in texting mode most of keys 30 can be toggled or pressed into a left position 38 or a right position 42 to select a letter or symbol corresponding thereto.

In the embodiment shown in FIG. 4, most of keys 30 are located above a corresponding depressible switch 36 similar to that described with respect to FIG. 3. In one embodiment, when a key is pressed downwardly by a user, a plunger pushes a top-most portion of the switch downwardly until it engages a contact disposed therebelow, thereby completing a circuit and indicating that the key has been actuated by a user. Simultaneously, sense and drive electrodes 50 and 60 sense and detect where on keyboard 10, and in which position, the user has pressed the key, for example at position 38 or 42 (the left and right positions shown in FIG. 4). Thus, hand-held device 20 receives first information or a first signal indicating the switch has been actuated or closed by a user at or about the same time that second information or a second signal is provided indicating into which particular position the key has been pressed by the user. The first information and second signals are preferably combined to yield third information or a third signal indicating which from among two symbols on a particular key on keyboard 10 the user has selected when device 20 is in texting mode.

Continuing to refer to FIG. 4, there is shown the location of a mutual capacitance sense and drive electrode array 55 superimposed on keyboard 10 thereof. As shown, a first plurality of drive electrodes 50 is disposed beneath rows 32 of keys 30 of keyboard 10, where the individual drive electrodes in each row are electrically independent of another. A second plurality of sense electrodes 60 is disposed beneath the columns of keys 30 of keyboard 10, where the individual sense electrodes in each column are electrically independent of another. In the embodiment illustrated in FIG. 4, the first plurality of drive electrodes 50 is substantially perpendicular to the second plurality of sense electrodes 60, and rows 32 and columns 34 of the drive and sense electrodes 50 and 60 respectively intersect at locations beneath keys 30, where two sense electrodes correspond to the left and right positions 38 and 42 of at least some of the keys 30, and are disposed beneath such keys. As further illustrated in FIG. 4, the drive and sense electrodes 50 and 60 form an array 55 configured in respect of keyboard 10 to is permit the first and second positions 38 and 42 corresponding to each of the keys 30, as the selected key portion is depressed by a user, to be detected by array 55. A switch 36 is disposed beneath such keys 30 is configured to be closed when depressed downwardly sufficiently far thereby to indicate selection of one of two symbols on the key, and optionally also permits a user's finger to be brought into close enough proximity to the electrode array 55 such that that the particular portion 38 or 42 of the key which the user is selecting and depressing may be sensed by the array 55. Alternatively, array 55 may be configured to detect the position of a user's finger on keyboard 10 even though no key 30 has been depressed.

Note that according to the particular application or keyboard at hand, drive electrodes 50 of FIG. 4 may alternatively be arranged in columns, while sense electrodes 60 of FIG. 4 may be arranged in rows. Note further that the rows or columns of sense and drive electrodes need not be arranged perpendicular in respect of one another, but instead may be arranged at any suitable angle. In addition, drive and sense electrodes 50 and 60 of FIG. 4 may be arranged substantially in a single plane, may be disposed on opposing surfaces of a suitable substrate 52, or may be otherwise suitably configured in respect of one another such as in multiple different planes. In the embodiment illustrated in FIG. 4, such a substrate 52 is preferably formed of a bendable or flexible material such as a flex circuit material.

Since sensing measurements are based on mutual capacitance, the row and column sensing configurations illustrated in FIGS. 1 through 4 may be employed to reduce the pin count to only 2n for an n×n electrode grid. Furthermore, such an electrode array configuration is conducive to being arranged as interleaved fingers, which increases the ability to use interpolation techniques in determining a user's finger location, and further reduces pin count requirements.

The embodiments of device 20 illustrated in FIGS. 1 through 4 operate in accordance with the principles of mutual capacitance. Capacitances are established between individual sense and drive electrodes by means of a drive waveform input to the drive electrodes. A user's finger is typically at or near electrical ground, and engages a key 30 on keyboard 10 that overlies array 55. When in contact with key 30, the user's finger couples to the drive signal provided by a drive electrode in closest proximity thereto and proportionately reduces the amount of capacitance between such drive electrode and its corresponding nearby sense electrode. That is, as the user's finger moves across keyboard 10 and/or as keys 30 are depressed, depending on how device 20 has been configured, the ratio of the drive signal coupled to the respective individual sense electrodes through the finger is reduced and varied, thereby providing a two-dimensional measurement of a position of the user's finger above keyboard 10 and/or on a given position on an individual key 30.

In such a manner, the capacitance at a single row-column intersection corresponding to the user's finger location or position on a given key is determined. By scanning all the rows and columns of array 55, a map of capacitance measurements may be created for all the nodes in the grid. Because each measurement probes only a single grid intersection point, no measurement ambiguities arise with multiple touches as in the case of some self-capacitance systems. Moreover, to measure a grid of n×n intersections, only 2n pins on an IC are required in device 20 illustrated in FIGS. 1 through 4. Thus, device 20 may be configured to scan all rows and all columns thereby to detect at least one location of the user's finger. Device 20 may also be configured to multiplex signals provided by the rows and the columns to a capacitance sensing circuit.

For some applications device 20 may further be configured to sense multiple touch locations in electrode array 55 substantially simultaneously. In one embodiment a host computer is updated at a rate of, for example, 60 Hz, where update rate results in fast but not altogether “simultaneous” measurements; all the rows and columns of array 55 are scanned sequentially to determine the position of any finger touches. More than one finger position on keyboard 10 can be detected at such an update rate even though technically such positions are not actually measured simultaneously.

It will now become apparent to those skilled in the art that many different electrode interleaving and electrode array configurations other than those shown or described explicitly in the drawings or specification hereof may be employed and yet fall within the scope of the invention. For example, in one embodiment the values of the individual capacitances associated with sense electrode columns 34 and drive electrode rows 32 may be monitored or measured by a capacitance sensing circuit, as may the operating states of switches 36 associated therewith. In a preferred embodiment, a 125 kHz square wave drive signal is applied sequentially to the individual rows of drive electrodes by capacitance sensing circuit 72, although those skilled in the art will understand that other types of drive signals may be successfully employed. Indeed, the drive signal need not be supplied by a capacitance sensing circuit, and in some embodiments is provided by a separate drive signal circuit. In a preferred embodiment, however, the drive signal circuit and the capacitance sensing circuit 72 are incorporated into a single circuit or integrated circuit.

Electrode array 55 may also include one or more ground traces disposed between individual drive and sense electrodes. Direct coupling of an electrical field between drive and sense electrodes is thereby reduced so that the majority of the coupling field lines in an electrical field may be interrupted by finger 60 instead of being drawn directly between such drive and sense electrodes, an effect which may become especially pronounced in the presence of humidity or water vapor. Further details concerning the use of such ground traces are to be found in U.S. patent application Ser. No. 11/945,832 to Harley entitled “Capacitive Sensing Input Device with Reduced Sensitivity to Humidity and Condensation” filed on Nov. 27, 2007, the entirety of which is hereby incorporated by reference herein.

FIG. 5 shows one embodiment of a circuit diagram for device 20. By way of example, an AVAGO™ AMRI-2000 integrated circuit may be employed to perform the functions of capacitance sensing circuit 72. A low-impedance AC waveform (e.g., a 100 kHz square wave) is provided to a drive electrode (not shown in FIG. 5) by signal generator 74. Operational amplifier 76 with feedback capacitor 78 is connected to a sense electrode, and holds the sense line at virtual ground. Amplifier 76 acts as a charge to voltage converter, providing a voltage measurement of the charge induced through capacitor 78. Subsequent filtering or synchronous demodulation is effected by demodulator 82 and used to extract low-frequency information from the generated AC signal. Variable capacitor 84 indicates the mutual capacitance between drive sense electrodes, as modulated by the presence of a finger (not shown in FIG. 5). Feedback capacitor 78 sets the gain of device 20. Those skilled in the art will appreciate that many circuits other than that shown in FIG. 5 may be employed to drive and sense electrode array 55. One example of an integrated circuit that may be adapted to drive and sense signals provided by electrode array 55 is an AVAGO™ AMRI-2000 integrated circuit.

Output signals provided by electrode array 55 and circuit 72 are preferably routed to a host processor via, for example, a serial I²C-compatible or Serial Peripheral Interface (SPI) bus. For example, an AVAGO™ AMRI-2000 integrated circuit may be programmed to provide output signals to a host processor via such busses. The host processor may use information provided by the AMRI-2000 integrated circuit to control a display.

While the primary use of the letter, number or symbol keyboard selection devices and methods disclosed herein is believed likely to be in the context of relatively small portable or hand-held electronic devices, as well as touchpads or touchscreens therefore, it may also be of value in the context of larger devices, including, for example, keyboards, touchscreens or touchpads associated with desktop computers or other less portable devices such as exercise equipment, industrial control panels, washing machines and the like. Similarly, while many embodiments of the invention are believed most likely to be configured for manipulation by a user's fingers, some embodiments may also be configured for manipulation by other mechanisms or body parts. For example, the invention might be located on or in the hand rest of a keyboard and engaged by the heel of the user's hand, or actuated by a pointer or stylus. Furthermore, the invention is not limited in scope to drive electrodes disposed in columns and sense electrodes disposed in rows. Instead, and as mentioned above, rows and columns are interchangeable in respect of sense and drive electrodes.

Note further that included within the scope of the present invention are methods of making and having made the various components, devices and systems described herein.

The above-described embodiments should be considered as examples of the present invention, rather than as limiting the scope of the invention. In addition to the foregoing embodiments of the invention, review of the detailed description and accompanying drawings will show that there are other embodiments of the present invention. Accordingly, many combinations, permutations, variations and modifications of the foregoing embodiments of the present invention not set forth explicitly herein will nevertheless fall within the scope of the present invention.

I claim:

1. A combined mutual capacitance and switch-actuated keyboard for an electronic device, comprising:
a keyboard comprising a plurality of keys arranged in rows and columns, at least some of the keys in the keyboard each having a single switch disposed therebeneath, each key and switch being configurable to present, assume or sense at least left and right positions according to how each such key is engaged, depressed, tilted or touched by a user's finger, namely a left position and a right position, each of the at least some keys having first and second symbols displayed thereon, the first and second symbols corresponding to the left and right positions of each of switches;
a first plurality of drive electrodes disposed beneath the rows or columns of the keyboard, the drive electrodes in each row or column being electrically independent of one another;
a second plurality of sense electrodes disposed beneath the rows or columns of the keyboard, the sense electrodes in each row or column being electrically independent of one another;
wherein the first plurality of drive electrodes is arranged at an angle with respect to the second plurality of sense electrodes, the rows and columns of drive and sense electrodes cross over but are electrically isolated from one another at locations beneath the at least some keys, at least two sense electrodes corresponding to the left and right positions are disposed beneath each of the at least some keys, the drive and sense electrodes form an array configured in respect of the keyboard to permit the first and second positions selected by the user's finger and corresponding to each of the at least some keys to be detected by the array, and each switch is configured to indicate the user's finger's selection of the first or second symbol.

2. The combined mutual capacitance and switch-actuated keyboard of claim 1, wherein the switch and key are finger-tiltable into the left and right positions.

3. The combined mutual capacitance and switch-actuated keyboard of claim 1, wherein the switch and key are finger-depressible into the left and right positions.

4. The combined mutual capacitance and switch-actuated keyboard of claim 1, wherein the array is further configured to detect the position of the user's finger on the keyboard even though no key has been depressed, tilted or touched.

5. The combined mutual capacitance and switch-actuated keyboard of claim 1, wherein the first plurality of drive electrodes is substantially perpendicular with respect to the second plurality of sense electrodes.

6. The combined mutual capacitance and switch-actuated keyboard of claim 1, wherein two sense electrodes and one drive electrode are disposed beneath each of the at least some keys.

7. The combined mutual capacitance and switch-actuated keyboard of claim 1, wherein the keyboard is a QWERTY keyboard.

8. The combined mutual capacitance and switch-actuated keyboard of claim 4, wherein the sense electrodes are arranged in fifteen columns and the drive electrodes are arranged in four rows.

9. The combined mutual capacitance and switch-actuated keyboard of claim 5, wherein the keyboard comprises four rows and five columns

10. The combined mutual capacitance and switch-actuated keyboard of claim 1, wherein each such switch and key is further configurable to assume a central position, and each of the at least some keys has a third symbol displayed thereon, the third symbol corresponding to the central position of each of the at least some keys, each such switch and key further being configured to indicate selection of the first, second or third symbol.

11. The combined mutual capacitance and switch-actuated keyboard of claim 10, wherein the central position of the switch and key is substantially untilted and finger-depressed.

12. The combined mutual capacitance and switch-actuated keyboard of claim 10, wherein three sense electrodes and one drive electrode are disposed beneath each of the at least some keys, the three sense electrodes corresponding to the left, central and right positions of each such switch and key.

13. The combined mutual capacitance and switch-actuated keyboard of claim 1, wherein the sense electrodes are arranged in nine columns and the drive electrodes are arranged in four rows.

14. The combined mutual capacitance and switch-actuated keyboard of claim 10, wherein the keyboard comprises four rows and three columns

15. The combined mutual capacitance and switch-actuated keyboard of claim 1, wherein each key comprises an electrically non-conductive material

16. The combined mutual capacitance and switch-actuated keyboard of claim 1, wherein the sense and drive electrode array is disposed in a pattern on flex circuitry.

17. The combined mutual capacitance and switch-actuated keyboard of claim 16, wherein the flex circuitry forms a keypad membrane.

18. The combined mutual capacitance and switch-actuated keyboard of claim 1, wherein each such switch comprises a depressible dome structure.

19. The combined mutual capacitance and switch-actuated keyboard of claim 1, wherein each switch comprises a plunger configured to engage a top portion of a depressible structure.

20. The combined mutual capacitance and switch-actuated keyboard of claim 1, wherein at least some of the symbols displayed on the at least some keys are alphanumeric.

21. The combined mutual capacitance and switch-actuated keyboard of claim 1, wherein the electronic device is a hand-held portable electronic device.

22. The combined mutual capacitance and switch-actuated keyboard of claim 21, wherein the hand-held portable electronic device is a mobile phone, personal data assistant (“PDA”), or a combined mobile phone and PDA.

23. The combined mutual capacitance and switch-actuated keyboard of claim 1, wherein at least one of the plurality of drive electrodes and the plurality of sense electrodes comprises indium tin oxide (ITO).

23. The combined mutual capacitance and switch-actuated keyboard of claim 1, further comprising a drive signal circuit configured to provide an electrical drive signal to the plurality of drive electrodes and operably connected thereto.

24. The combined mutual capacitance and switch-actuated keyboard of claim 23, wherein the drive signal circuit is incorporated into an integrated circuit.

25. The combined mutual capacitance and switch-actuated keyboard of claim 1, further comprising a capacitance sensing circuit operably coupled to the plurality of sense electrodes and configured to detect changes in capacitance occurring therein or thereabout.

26. The combined mutual capacitance and switch-actuated keyboard of claim 25, wherein the capacitance sensing circuit is incorporated into an integrated circuit.

27. The combined mutual capacitance and switch-actuated keyboard of claim 1, wherein the keyboard is incorporated into or forms a portion of an LCD, a computer display, a laptop computer, a personal data assistant (PDA), a mobile telephone, a radio, an MP3 player, a portable music player, a stationary device, a television, a stereo, an exercise machine, an industrial control, a control panel, an outdoor control device and a washing machine.

28. The combined mutual capacitance and switch-actuated keyboard of claim 1, wherein the keyboard forms a portion of a touchscreen or a touchpad.

29. The combined mutual capacitance and switch-actuated keyboard of claim 1, wherein the keyboard is configured to scan the first and second pluralities of rows and columns thereby to detect the at least one location.

30. The combined mutual capacitance and switch-actuated keyboard of claim 1, wherein the keyboard is configured to multiplex signals provided by at least one of the first and second pluralities of rows and the columns.

31. The combined mutual capacitance and switch-actuated keyboard of claim 1, wherein the keyboard is configured to sense multiple locations in the array simultaneously.

32. A method of generating text messages with an electronic device, comprising:
a user's finger engaging, touching, depressing or tilting a key on a keypad to or in a left position or a right position to select one of at least two letters, numbers or symbols displayed on the key at the left and right positions, respectively;
capacitively sensing, using at least first and second sense electrodes disposed beneath the left and right positions of the key, and at least one drive electrode disposed beneath the key, the letter, number or symbol that has been selected by the user's finger; and
causing a single switch disposed beneath each such key to indicate which of the left and right positions has been selected by the user's finger;
wherein the switch is mechanically, capacitively or resistively configurable to indicate the left and right positions according to whether the user's finger selects the left position or the right position.

33. The method of claim 29, further comprising:
the user's finger selecting the key on the keypad in a central position to select one of at least three letters, numbers or symbols displayed on the key at the central position, and
capacitively sensing, using at least a third sense electrode disposed beneath the central position of the key, and at least one drive electrode disposed beneath the key, the letter, number or symbol that has been selected by the user;
wherein the switch is further mechanically, capacitively or resistively configurable to indicate the central position according to whether the user's finger selects the central position.
